(19) United States
(12) Patent Application Publication
(10) Pub. No.: US 2025/0344394 A1
(43) Pub. Date: Nov. 6, 2025

(54) NAND FLASH MEMORY AND MANUFACTURING METHOD THEREOF

(71) Applicant: Winbond Electronics Corp., Taichung City (TW)

(72) Inventor: Riichiro Shirota, Taichung City (TW)

(73) Assignee: Winbond Electronics Corp., Taichung City (TW)

(21) Appl. No.: 19/068,003

(22) Filed: Mar. 3, 2025

(30) Foreign Application Priority Data
May 1, 2024 (JP) 2024-074328
May 13, 2024 (JP) 2024-077743
Aug. 20, 2024 (JP) 2024-139175

(51) Int. Cl. H10B 43/35

(52) U.S. Cl. CPC H10B 43/35

(57) ABSTRACT

A NAND flash memory capable of reducing capacitive coupling between adjacent memory cells and a manufacturing method thereof are provided. The NAND flash memory includes an active region, formed by extending along a bit line direction within a silicon substrate; a trench isolation region, used to define the active region; and a charge storage layer, formed on the active region corresponding to each memory cell and stacked with a SiN layer sandwiched between insulating layers; a first control gate, formed on the charge storage layer corresponding to each memory cell; and a second control gate, extending along a word line direction and formed on the first control gate. The second control gate is electrically connected to multiple first control gates in a corresponding row direction, and the trench isolation region is aligned with sidewalls of the first control gate and the charge storage layer.

### CROSS-REFERENCE TO RELATED APPLICATION

This application claims the priority benefit of Japan Application No. 2024-074328, filed on May 1, 2024, Japan Application No. 2024-077743, filed on May 13, 2024, and Japan Application No. 2024-139175, filed on Aug. 20, 2024. The entirety of each of the above-mentioned patent applications is hereby incorporated by reference herein and made a part of this specification.

### BACKGROUND

### Technical Field

The disclosure relates to a non-volatile semiconductor memory device, and more particularly to a NAND flash memory with a two-dimensional (2D) structure.

### Description of Related Art

The cell structure of the NAND flash memory adopts a floating gate structure. The floating gate includes, for example, polysilicon and has excellent charge retention characteristics. In addition, a highly reliable NAND flash memory that suppresses influence caused by floating gate coupling between memory cells is also disclosed (for example, Japanese Patent Application Laid-Open No. 2017-097927).

In a conventional NAND flash memory with a two-dimensional structure of the FG type, due to size miniaturization, coupling effect of parasitic capacitance between floating gates or between a floating gate and a control gate of adjacent memory cells is greater. For example, charges of the floating gates of adjacent memory cells sometimes causes a threshold (Vth) of a programmed memory cell to change. As a result, there are problems such as a widened threshold distribution of the memory cell and reduction in reliability of the NAND flash memory.

In order to solve the existing issues, the disclosure provides a NAND flash memory capable of reducing capacitive coupling between adjacent storage memory cells and a manufacturing method thereof.

### SUMMARY

A NAND flash memory of the disclosure includes an active region, formed by extending along a bit line direction within a semiconductor substrate; a trench isolation region, used to define the active region; a charge storage layer, formed in the active region corresponding to each memory cell and including a nitride layer sandwiched between insulating layers; a first conductive layer, formed on the charge storage layer corresponding to each memory cell; and a second conductive layer, extending along a word line direction and formed on the first conductive layer. The second conductive layer is electrically connected to multiple first conductive layers in a corresponding row direction, the trench isolation region is aligned with sidewalls of the first conductive layer and the charge storage layer.

In an embodiment, the charge storage layer includes an oxide-nitride-oxide (ONO) structure, a stacked structure including multiple insulating films other than oxide is included between a silicon substrate and the nitride layer, or a stacked structure including multiple insulating films other than oxide is included between the nitride and the first conductive layer. In an embodiment, the first conductive layer includes a polysilicon layer, the semiconductor substrate includes a silicon region, and the charge storage layer includes a silicon-oxide-nitride-oxide-silicon (SONOS) structure. In an embodiment, the trench isolation region is formed in a self-aligned manner when etching the first conductive layer, the charge storage layer, and the semiconductor substrate. In an embodiment, a peripheral region of the NAND flash memory includes a gate insulating film and a gate material separated from the charge storage layer and the first conductive layer.

A manufacturing method of a NAND flash memory of the disclosure includes the following steps. A stack of a charge storage layer including a nitride layer sandwiched between insulating layers and a first conductive layer are formed on a semiconductor substrate. The first conductive layer, the charge storage layer, and the semiconductor substrate are simultaneously etched, the first conductive layer and the charge storage layer are patterned along a bit line direction, and a trench for defining an active region is formed on the semiconductor substrate. The trench is filled with an insulating material. A second conductive layer is conformally formed on the semiconductor substrate including the first conductive layer. The second conductive layer, the first conductive layer, and the charge storage layer are simultaneously etched, and the second conductive layer, the first conductive layer, and the charge storage layer are patterned along a word line direction. A source/drain doped region is formed in the active region after removing the second conductive layer, the first conductive layer, and the charge storage layer.

In an embodiment, the manufacturing method further includes the following steps. A mask pattern covering a cell array region is formed, the charge storage layer and the first conductive layer in a peripheral region are removed. A gate insulating film and a gate material separated from the charge storage layer and the first conductive layer are formed in the peripheral region. In an embodiment, the manufacturing method further includes the following steps. A gate insulating film and a gate material are conformally formed on the semiconductor substrate. The gate insulating film and the gate material are planarized until the first conductive layer in the cell array region is exposed.

According to the disclosure, the charge storage layer including the nitride layer is formed corresponding to each memory cell, so that compared with an FG-type memory cell, capacitive coupling between adjacent memory cells may be reduced, and the threshold distribution of the memory cell may be narrowed. In addition, through aligning the trench isolation region for defining the active region with the charge storage layer and the first conductive layer, capacitive coupling between adjacent memory cells may be reduced while implementing high integration of a cell array.

### BRIEF DESCRIPTION OF THE DRAWINGS

FIG. 1 is a schematic diagram of a cross section of a cell array region of a conventional NAND flash memory with a two-dimensional structure in a direction perpendicular to a bit line.

FIG. 2A and FIG. 2B are diagrams of a NAND flash memory with a two-dimensional structure according to an embodiment of the disclosure, wherein FIG. 2A is a plan diagram of a part of a cell array, and FIG. 2B is a schematic diagram of a cross section taken along a line A-A of FIG. 2A.

FIG. 3A to FIG. 3C are schematic diagrams of a manufacturing process of a cell array region of a NAND flash memory according to an embodiment of the disclosure.

FIG. 4A to FIG. 4D are schematic diagrams of a manufacturing process of a cell array region of a NAND flash memory according to an embodiment of the disclosure.

FIG. 5A is a plan diagram of a substrate when etching a first control gate, a charge storage layer, and a substrate through mask patterns, and FIG. 5B is a plan diagram of the substrate when the heights of the first control gate and a trench insulator are the same.

FIG. 6A to FIG. 6D are schematic diagrams of a manufacturing process of a cell array region and a peripheral region of a NAND flash memory of the embodiment.

FIG. 6E and FIG. 6F are schematic diagrams of another manufacturing process of a cell array region and a peripheral region of a NAND flash memory of the embodiment.

FIG. 7A to FIG. 7C are schematic diagrams of a manufacturing process of a cell array region and a peripheral region of a NAND flash memory of the embodiment.

FIG. 8 is a schematic diagram of a cross section of a cell array region of a NAND flash memory in a bit line direction of the embodiment.

### DESCRIPTION OF THE EMBODIMENTS

A NAND flash memory with a two-dimensional structure of the disclosure uses silicon nitride (SiN) as a charge storage layer, such as using a silicon-oxide-nitride-oxide-silicon (SONOS) charge storage layer to implement narrowing of a threshold distribution (Vth) of a memory cell. In addition, the NAND flash memory of the disclosure is used as a storage medium in various semiconductor devices (for example, a microcontroller, a microprocessor, a logic device, etc. in which such a flash memory is embedded).

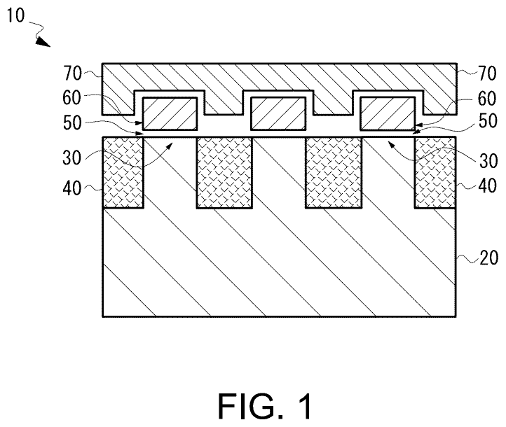

FIG. 1 is a cross-sectional diagram of a cell array of a conventional NAND flash memory with a two-dimensional structure in a direction intersecting with a NAND string, that is, a word line direction. As shown in FIG. 1, a conventional NAND flash memory 10 forms active regions 30 extending along a bit line direction on a P-type semiconductor substrate or a P well 20, wherein each active region 30 is isolated by a trench 40.

The active region 30 provides a channel region or an N-type source/drain (S/D) diffusion region for the memory cell. In the active region 30, a patterned floating gate 60 corresponding to each memory cell is formed through a gate oxide film (or tunneling oxide film) 50, and a control gate 70 extending along the word line direction is formed on the floating gate 60. The floating gate 60 includes, for example, doped conductive polysilicon. The control gate 70 includes, for example, conductive polysilicon and a metal material such as tungsten. The floating gate 60 is capacitively coupled to the control gate 70 via an upper dielectric layer.

When the memory cell is programmed, charges tunneled from the channel region of the active region 30 via the gate oxide film 50 are stored in the floating gate 60. When the memory cell is erased, the charges accumulated in the floating gate 60 are tunneled through the gate oxide film 50 and discharged to the channel region.

Along with miniaturization of the manufacturing process, the spacing between the floating gates 60 of adjacent memory cells decreases, and capacitive coupling between the adjacent floating gates 60 increases. For example, the charges accumulated in the floating gate 60 of the programmed memory cell may affect the threshold of an adjacent memory cell.

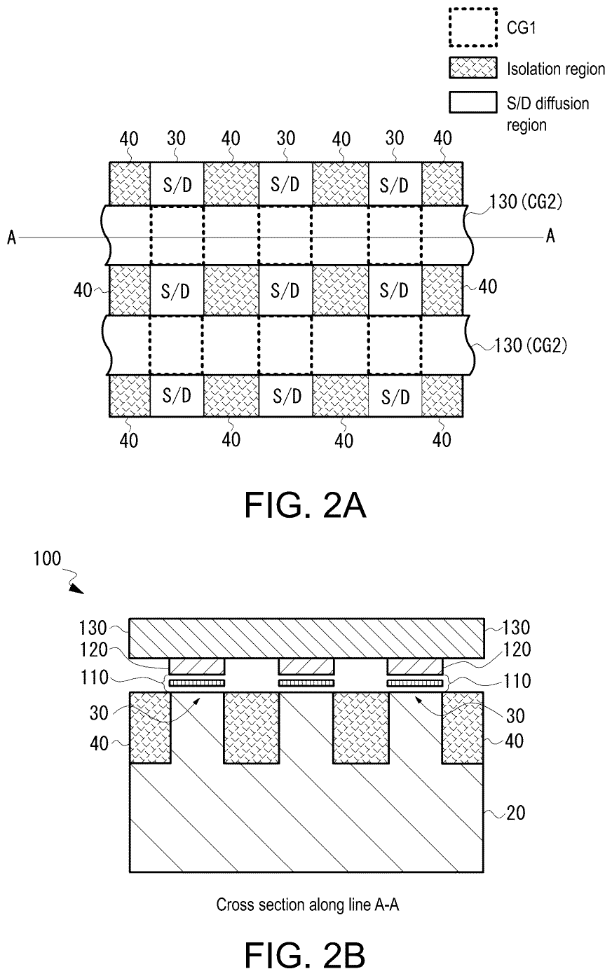

FIG. 2A and FIG. 2B are diagrams of a NAND flash memory with a two-dimensional structure according to an embodiment of the disclosure. In a NAND flash memory 100 of the embodiment, a charge storage layer 110 formed by stacking multiple insulating layers with SiN layers sandwiched therebetween is formed on the active region 30 to replace the floating gate 60. The patterned charge storage layer is correspondingly formed on the active region 30 of each memory cell. The charge storage layer 110 may, for example, have an oxide-nitride-oxide (ONO) structure, or multiple insulating films may be stacked between a silicon substrate and a nitride layer instead of a single oxide layer. In addition, multiple insulating films may be stacked between nitride and a gate instead of a single oxide layer. A first control gate (CG1) 120 is formed on the charge storage layer 110 and is patterned to correspond to the charge storage layer 110. The first control gate 120 includes, for example, doped conductive polysilicon or may be formed by stacking multiple low resistance materials (for example, TaN) and other metal layers. A patterned second control gate (CG2) 130 extending along the word line direction (a row direction) is formed on the first control gate 120. The second control gate 130 is electrically connected to the first control gate 120. The ideal second control gate 130 has low resistance and includes, for example, a metal material such as Al and Cu. In addition, the first control gate 120 may include the same material as or a different material than the second control gate 130.

As described above, the charge storage layer 110 has, for example, the oxide-nitride-oxide (ONO) structure, and the ONO structure jointly forms a SONOS structure between the silicon substrate (or a silicon well) and the first control gate 120 including polysilicon. During a program operation, the charge storage layer 110 stores charges obtained by Fowler-Nordheim (FN) tunneling from the channel region to the oxide at an interface of the nitride layer. During an erase operation, the charges stored in the charge storage layer 110 are discharged to the channel region by FN tunneling through the oxide layer.

In the embodiment, the thickness of the nitride layer (SiN layer) of the charge storage layer 110 is relatively less than the thickness of a floating gate of an FG structure, and the nitride layer is an insulating film. Therefore, compared with the FG structure, capacitive coupling between adjacent memory cells may be reduced. As a result, the threshold distribution of the memory cell may be narrowed. In addition, in the case where the nitride layer of the charge storage layer 110 is continuously formed along the word line direction (in the case of being not separated corresponding to each memory cell), if electrons retained in the nitride layer are attracted by electric holes and move or the electric holes are attracted by the electrons and move, issues such as the threshold of the memory cell changing may occur. However, through separating the charge storage layer according to each memory cell as in the embodiment, the issue may be eliminated.

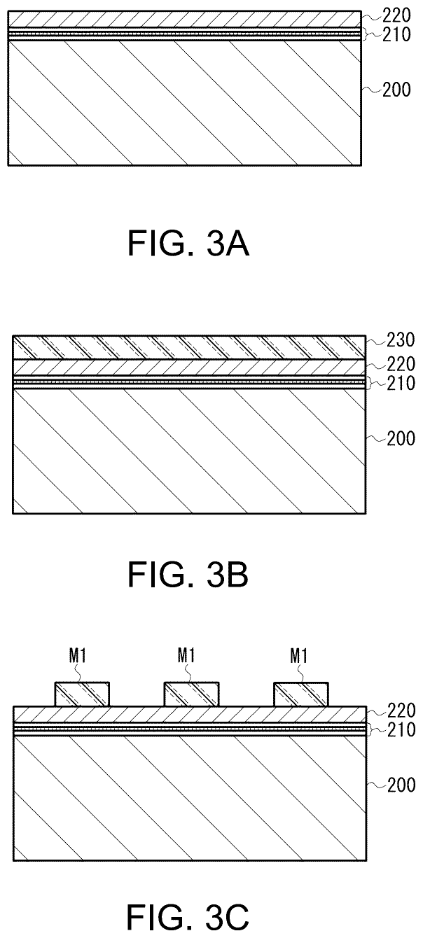

Next, a manufacturing process of a cell array region of a NAND flash memory of the embodiment will be described with reference to FIG. 3A to FIG. 5B. As shown in FIG. 3A, on a surface of a P-type silicon substrate or P well 200 (hereinafter referred to as a substrate for convenience), a charge storage layer 210 with a three-layer structure is, for example, formed through chemical vapor deposition (CVD) and includes, for example, an oxide film such as SiO₂, a nitride film such as Si₃N₄, and an oxide film such as SiO₂. In addition, on the charge storage layer 210, a first control gate 220 made of, for example, polycrystalline silicon is formed.

Next, as shown in FIG. 3B, a mask material 230 of a resist may be formed. Next, the mask material 230 is patterned through a lithography process, as shown in FIG. 3C, to form mask patterns M1 spaced at specific intervals and extending along the bit line direction.

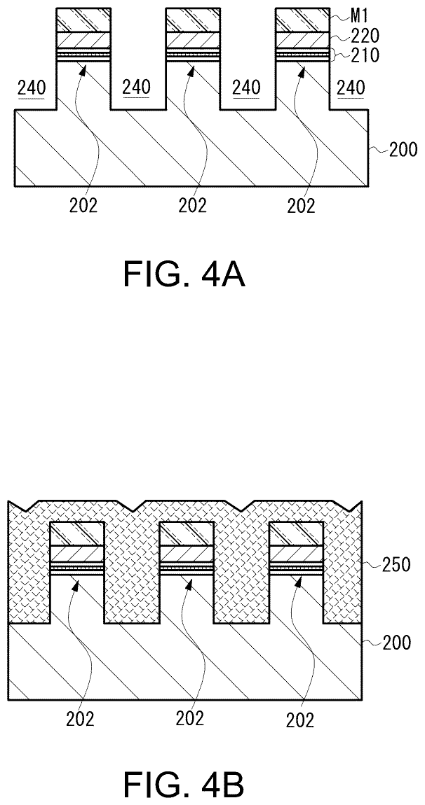

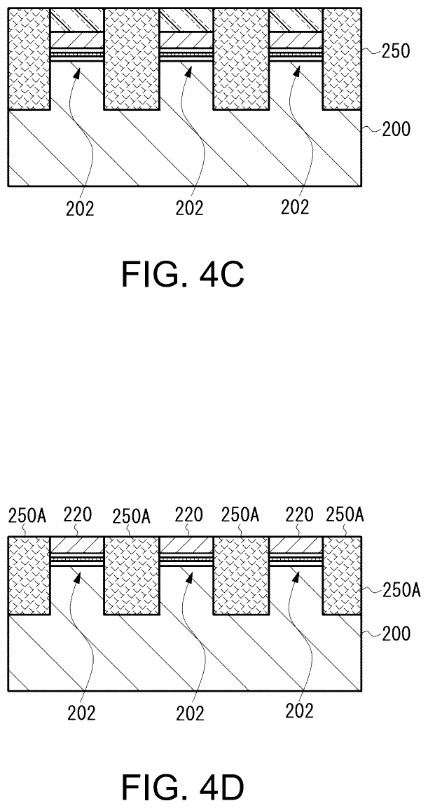

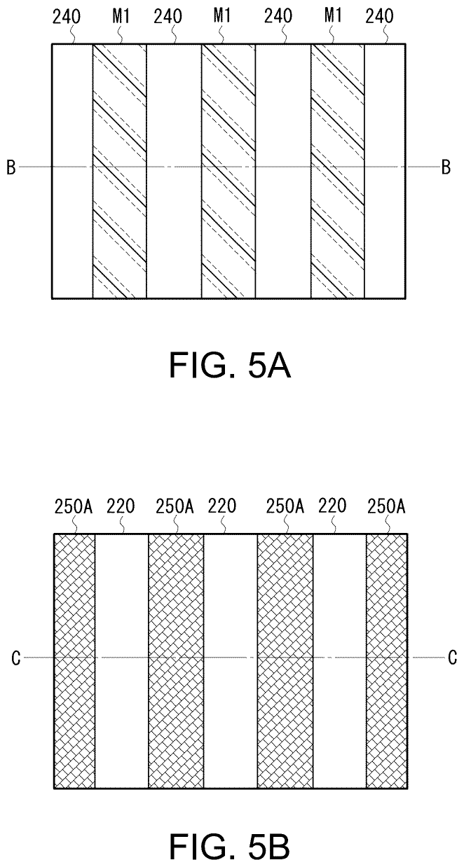

Next, as shown in FIG. 4A, the exposed first control gate 220, charge storage layer 210, and substrate 200 are simultaneously anisotropically etched through the mask patterns M1 to form a stack of the patterned charge storage layer 210 and first control gate 220 on the substrate 200, while forming a trench 240 for defining an active region 202 on the substrate 200. FIG. 5A is a plan diagram of a substrate when etching the first control gate 220, the charge storage layer 210, and the substrate 200 through the mask patterns M1, and FIG. 4A corresponds to a cross section taken along a line B-B of FIG. 5A.

The stack of the charge storage layer 210 and the first control gate 220 extends along the bit line direction, and the trench 240 is self-aligned with a sidewall of the stack of the charge storage layer 210 and the first control gate 220. Therefore, the trench 240 is formed with high accuracy without positional error between the stack of the charge storage layer 210 and the first control gate 220. In addition, since the charge storage layer 210 is covered by the first control gate 220, the charge storage layer 210 is protected from being etched.

Next, as shown in FIG. 4B, an insulating film 250 is conformally formed on the substrate 200 including the trench 240. Then, the insulating film 250 is etched to near a surface of the substrate 200, so that a trench insulator 250A is kept within the trench 240. At this time, the mask patterns M1 protect the first control gate 220 from being etched.

Next, as shown in FIG. 4C, the trench insulator 250A is planarized by surface polishing to expose surfaces of the mask patterns M1. Next, as shown in FIG. 4D, the mask patterns M1 are removed, and a surface of the trench insulator 250A is polished, so that the height of the trench insulator 250A is substantially the same as the height of the first control gate 220. In this way, the active region 202 extending along the bit line direction is isolated by the trench insulator 250A, and the stack of the charge storage layer 210 and the first control gate 220 is formed in the active region 202. FIG. 5B is a plan diagram of the substrate when the heights of the first control gate 220 and the trench insulator 250A are substantially the same, and FIG. 4D corresponds to a cross section taken along a line C-C of FIG. 5B. Furthermore, in some embodiments, the manufacturing process shown in FIG. 4D may not be required.

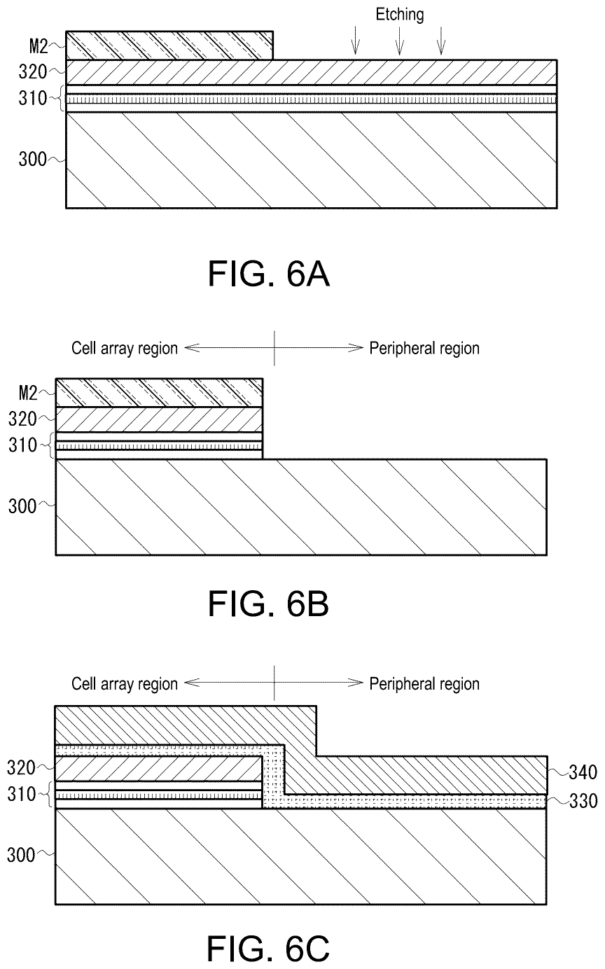

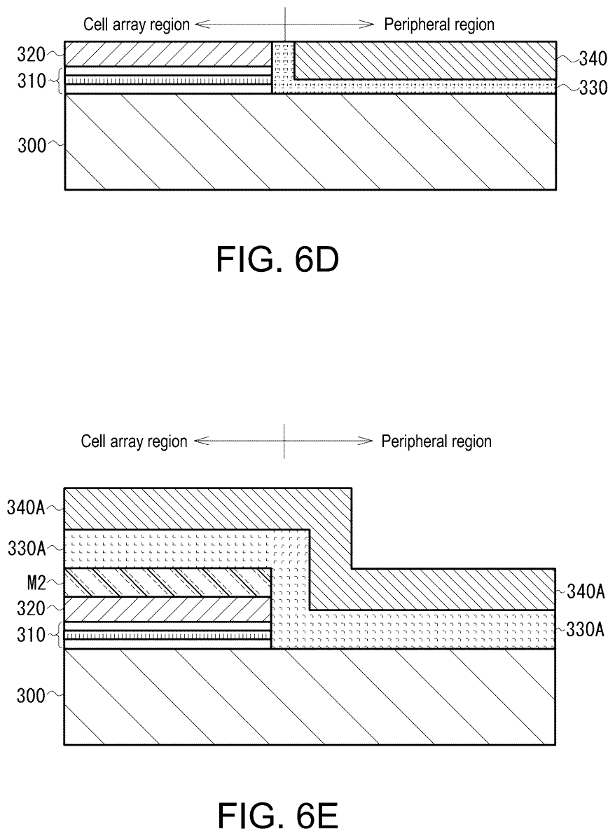

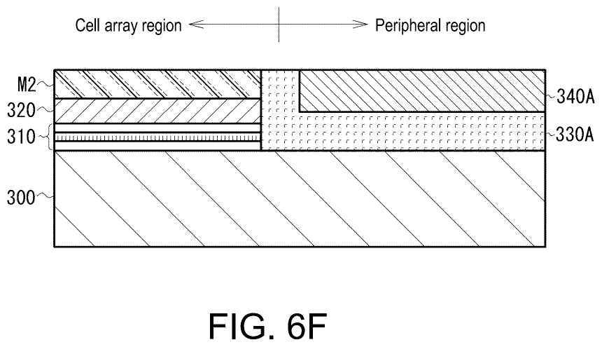

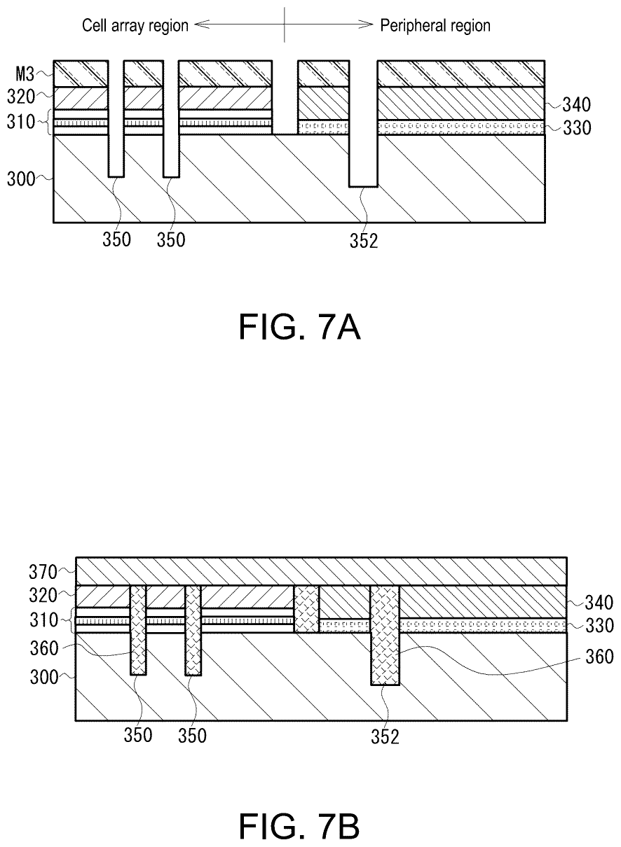

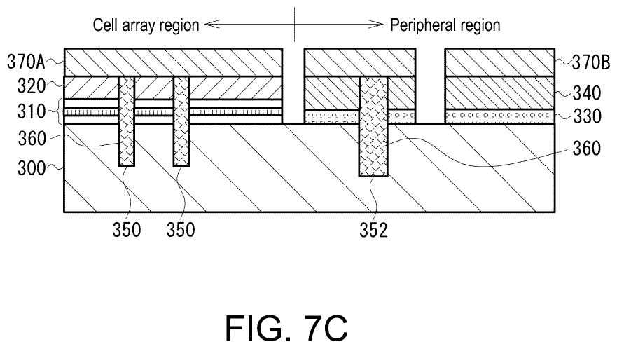

Next, manufacturing processes of a cell array region and a peripheral region in a flash memory of the embodiment will be described with reference to FIG. 6A to FIG. 6F and FIG. 7A to FIG. 7C. As shown in FIG. 6A, a charge storage layer 310 and a first control gate (CG1) 320 are conformally formed on a P-type silicon substrate 300. Then, a mask pattern M2 covering the cell array region is formed. Next, as shown in FIG. 6B, the mask pattern M2 is used as an etch mask to remove the charge storage layer 310 and the first control gate 320 in the peripheral region through etching.

Next, after removing the mask pattern M2, as shown in FIG. 6C, a gate insulating film 330 is conformally formed on the substrate 200 including the peripheral region. The gate insulating film 330 is, for example, a silicon oxide film. A page buffer/sense amplifier, a decoder, etc., are formed in the peripheral region, and the circuits include transistors driven by high voltage or transistors driven by low voltage. Therefore, the gate insulating film 330 is formed in various thicknesses, such as a thick film suitable for high voltage and a thin film suitable for low voltage. After the gate insulating film 330 is formed, a gate material 340 for the transistor in the peripheral region is conformally formed on the substrate 200. The gate material 340 is, for example, polysilicon.

Next, the gate insulating film 330 and the gate material 340 are etched back or planarized, as shown in FIG. 6D, so that the first control gate 320 is exposed in the cell array region and the gate material 340 is exposed in the peripheral region. Via the manufacturing processes, the charge storage layer 310 and the first control gate 320 in the cell array region and the gate insulating film 330 and the gate material 340 in the peripheral region may be separately formed. It should be noted that in a conventional FG-type flash memory, a floating gate of a cell array region is connected to a floating gate of a peripheral region (the floating gate is electrically connected to a control gate and serves as a gate of a transistor).

During the manufacturing process, after the mask pattern M2 is removed, the gate insulating film 330 and the gate material 340 are formed, but just as an example, and the mask pattern M2 may also be kept. As shown in FIG. 6E, a gate insulating film 330A and a gate material 340A are conformally formed on the substrate including the mask pattern M2. In this case, in the case where the gate insulating film 330A in the peripheral region is a thick insulating film with high withstand voltage, the height of the mask pattern M2 in the cell array region is substantially the same as that of the gate material 340A. In addition, the gate insulating film 330 at a boundary between the cell array region and the peripheral region is a thick insulating film with high withstand voltage.

Next, as shown in FIG. 6F, a planarization process is performed to expose the mask pattern M2 in the cell array region and the gate material 340A in the peripheral region, and the mask pattern M2 is removed. Via the manufacturing processes, the charge storage layer 310 and the first control gate 320 in the cell array region and the gate insulating film 330A and the gate material 340A in the peripheral region may be separately formed.

After respectively forming the first control gate 320 in the cell array region and the gate material 340 in the peripheral region, a mask pattern M3 as shown in FIG. 7A is formed. The gate material, the gate insulating film, and silicon in the cell array region and the peripheral region are simultaneously etched to form a trench 350 and a trench 352 on the substrate 300. The trench 350 in the cell array region may have a different size and/or a different depth than the trench 352 in the peripheral region.

After removing the mask pattern M3, as shown in FIG. 7B, an insulating material 360 is filled into the trench 350 and the trench 352. The insulating material 360 is, for example, a silicon oxide film. Next, the insulating material 360 is planarized to expose surfaces of the first control gate 320 and the gate material 340.

Next, as shown in FIG. 7B, a conductive material 370 serving as a precursor of the second control gate is conformally formed on the substrate 300 including the first control gate 320 and the gate material 340. The conductive material 370 is not particularly limited and may be, for example, a metal material such as Al or Cu. The conductive material 370 is electrically connected to the first control gate 320 and the gate material 340. In addition, metal silicide may also be formed between the conductive material 370 and the first control gate 320 and the gate material 340.

Next, as shown in FIG. 7C, the conductive material 370 in a region where the charge storage layer 310 and the first control gate 320 are formed within the cell array is patterned in a manner extending along the word line direction to form a second control gate 370A. The second control gate 370A is electrically connected to multiple first control gates 320 in the corresponding row direction and provides a word line. In addition, through patterning the conductive material 370, the first control gate 320 and the charge storage layer 310 thereunder are simultaneously etched to expose the active region. On the other hand, through patterning the conductive material 370, a wiring layer 370B electrically connected to the gate material 340, etc. is formed in the peripheral region.

After patterning the second control gate 370A, ion implantation is performed in the exposed active region 202 to form N-type dopants for source/drain. Moreover, similar to the conventional NAND flash memory, a bit line BL and a source line SL are formed in the cell array region.

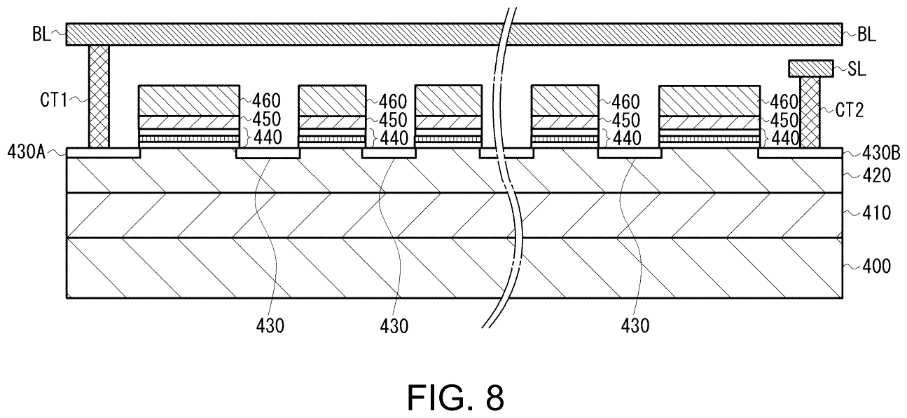

FIG. 8 is a cross section in the bit line direction in the cell array region, that is, a cross section in a direction perpendicular to a line A-A of FIG. 2A. As shown in FIG. 8, an N-well 410 is formed on a P-type silicon substrate 400, and a P-well 420 is formed within the N-well 410. An N-type source/drain diffusion region 430 for constructing a memory cell of a NAND string, a bit line side select transistor, and a source line side select transistor is formed on a surface of the P-well 420. A charge storage layer 440 is formed on the P-well 420, and a first control gate 450 and a second control gate 460 are formed on the charge storage layer 440. A diffusion region 430A of the bit line side select transistor is electrically connected to the bit line BL via a contactor CT1, and a diffusion region 430B of the source line side select transistor is electrically connected to the source line SL via a contactor CT2.

The NAND flash memory with the two-dimensional structure of the embodiment has an insulator stack (the charge storage layer) including the insulating layer for storing the charges, such as the SiN layer, between silicon and the control gate. The control gate is composed of two layers, that is, the first control gate CG1 formed on the insulator stack and the second control gate CG2 formed on the first control gate CG1. The insulator stack and the first control gate CG1 are sequentially deposited on silicon, and the first control gate CG1, the insulator stack, and silicon are simultaneously etched, and the trench is filled with the insulating material, thereby forming a shallow trench isolation region in a self-aligned manner. After the insulating material filling the trench is planarized, the second control gate CG2 is deposited on the first control gate CG1, so that the first control gate CG1 and the second control gate CG2 are electrically connected to each other.

The second control gate, the first control gate, and the charge storage layer are simultaneously etched to form multiple rectangular word lines WL. In this way, the charge storage layer is isolated from adjacent cells. An end portion of the word line of the cell array region is connected to a row decoder, and the row decoder applies a bias voltage for a read/write (program/erase) operation to the word line WL.

In the embodiment, the charge storage layer composed of the three-layer structure of oxide-nitride-oxide is shown, but not limited thereto, and the charge storage layer having four or more layers including nitride may also be used. In addition, the memory cell may be a single level cell (SLC) storing 1 bit (binary data) or may be other types storing multiple bits.

Although the preferred embodiments of the disclosure have been described in detail, the disclosure is not limited to the specific embodiments, and various modifications and changes may be made within the scope of the disclosure described in the claims.

What is claimed is:

1. A NAND flash memory, comprising:
an active region, formed by extending along a bit line direction within a semiconductor substrate;
a trench isolation region, used to define the active region;
a charge storage layer, formed in the active region corresponding to each memory cell and comprising a nitride layer sandwiched between insulating layers;
a first conductive layer, formed on the charge storage layer corresponding to each memory cell; and
a second conductive layer, extending along a word line direction and formed on the first conductive layer, wherein
the second conductive layer is electrically connected to a plurality of first conductive layers in a corresponding row direction,
the trench isolation region is aligned with sidewalls of the first conductive layer and the charge storage layer.

2. The NAND flash memory according to claim 1, wherein the charge storage layer comprises an oxide-nitride-oxide structure.

3. The NAND flash memory according to claim 1, wherein a stacked structure of a plurality of insulating films other than oxide is comprised between a silicon substrate and the nitride layer.

4. The NAND flash memory according to claim 1, wherein a stacked structure of a plurality of insulating films other than oxide is comprised between the nitride and the first conductive layer.

5. The NAND flash memory according to claim 1, wherein the first conductive layer comprises a polysilicon layer, the semiconductor substrate comprises a silicon region, and the charge storage layer comprises a silicon-oxide-nitride-oxide-silicon structure.

6. The NAND flash memory according to claim 1, wherein the trench isolation region is formed in a self-aligned manner when etching the first conductive layer, the charge storage layer, and the semiconductor substrate.

7. The NAND flash memory according to claim 1, wherein a peripheral region of the NAND flash memory comprises a gate insulating film and a gate material separated from the charge storage layer and the first conductive layer.

8. A manufacturing method of a NAND flash memory, comprising:
forming a stack of a charge storage layer comprising a nitride layer sandwiched between insulating layers and a first conductive layer on a semiconductor substrate;
simultaneously etching the first conductive layer, the charge storage layer, and the semiconductor substrate, patterning the first conductive layer and the charge storage layer along a bit line direction, and forming a trench for defining an active region on the semiconductor substrate;
filling the trench with an insulating material;
conformally forming a second conductive layer on the semiconductor substrate comprising the first conductive layer;
simultaneously etching the second conductive layer, the first conductive layer, and the charge storage layer, and patterning the second conductive layer, the first conductive layer, and the charge storage layer along a word line direction; and
forming a source/drain doped region of the active region after removing the second conductive layer, the first conductive layer, and the charge storage layer.

9. The manufacturing method according to claim 8, further comprising:
forming a mask pattern covering a cell array region, and removing the charge storage layer and the first conductive layer in a peripheral region; and
forming a gate insulating film and a gate material separated from the charge storage layer and the first conductive layer in the peripheral region.

10. The manufacturing method according to claim 8, further comprising:
conformally forming a gate insulating film and a gate material on the semiconductor substrate; and
planarizing the gate insulating film and the gate material until the first conductive layer in a cell array region is exposed.

11. The manufacturing method according to claim 8, wherein the charge storage layer comprises an oxide-nitride-oxide structure.

12. The manufacturing method according to claim 8, wherein a stacked structure of a plurality of insulating films other than oxide is comprised between a silicon substrate and the nitride layer.

13. The manufacturing method according to claim 8, wherein a stacked structure of a plurality of insulating films other than oxide is comprised between the nitride and the first conductive layer.

14. The manufacturing method according to claim 8, wherein the first conductive layer comprises a polysilicon layer, the semiconductor substrate comprises a silicon region, and the charge storage layer comprises a silicon-oxide-nitride-oxide-silicon structure.
